(19) United States
(12) Patent Application Publication
(10) Pub. No.: US 2024/0308328 A1
(43) Pub. Date: Sep. 19, 2024

(54) METHOD FOR COOLING A DRIVE SYSTEM

(71) Applicant: ZF Friedrichshafen AG, Friedrichshafen (DE)

(72) Inventors: Michael Grossmann, Horgenzell (DE); Franz Bitzer, Friedrichshafen (DE); Markus Eisele, Friedrichshafen (DE)

(73) Assignee: ZF Friedrichshafen AG, Friedrichshafen (DE)

(21) Appl. No.: 18/603,807

(22) Filed: Mar. 13, 2024

(30) Foreign Application Priority Data
Mar. 16, 2023 (DE) 10 2023 202 373.3

(51) Int. Cl. B60K 11/02; B60K 1/00; H05K 7/20

(52) U.S. Cl. CPC B60K 11/02; H05K 7/20927; H05K 7/20945; B60K 2001/003

(57) ABSTRACT

A method (8) is disclosed for cooling a drive system having a first component (1), a second component (2), and a common cooling circuit (3). The drive system is designed such that the common cooling circuit (3) is suitable for cooling the first component (1) and the second component (2), where the first component (1) has a first maximum temperature and a first threshold temperature, and where the first threshold temperature is lower than the first maximum temperature. The second component (2) has a second maximum temperature, where the first maximum temperature is lower than the second maximum temperature, and when the first threshold temperature is reached a cooling performance applied to cool the second component (2) is reduced.

### RELATED APPLICATIONS

This application claims the benefit of and right of priority under 35 U.S.C. § 119 to German Patent Application no. 10 2023 202 373.3, filed on 16 Mar. 2023, the contents of which are incorporated herein by reference in its entirety.

### FIELD OF THE DISCLOSURE

The invention relates to a method for cooling a drive system, a cooling system, a vehicle, a computer program, and a computer-readable medium as variously disclosed herein.

### BACKGROUND

An electric drivetrain typically comprises at least one electric motor and an inverter, which transforms a direct voltage supplied by a battery into an alternating voltage required by the electric motor. In such an electric drivetrain, the electric motor is typically cooled by an air-oil mixture. In turn, this air-oil mixture is typically cooled via an oil-water heat exchanger by a water-glycol cooling circuit. Typically, the inverter is also cooled by the same water-glycol circuit.

In such electric drivetrains, the inverter typically has a maximum permissible temperature (also referred to as the maximum temperature) that is lower than that of the electric motor. If the cooling system of such an electric drivetrain is operated at the limits of its power, then typically the inverter is the first to reach its maximum permissible temperature, i.e., it does so before the electric motor, and it is therefore switched off. Thus, a vehicle in which the electric drivetrain is installed cannot continue driving. Rather, the vehicle has to wait for the inverter to cool down again before driving on.

This has the disadvantage that during the standstill phase the vehicle is not available to its user.

### SUMMARY

The purpose of the present invention is to overcome, or at least to reduce the disadvantages associated with the prior art.

This objective is achieved by a method for cooling a drive system, wherein the drive system comprises a first component and a second component, wherein the drive system comprises a common cooling circuit, wherein the drive system is designed such that the common cooling circuit is suitable for cooling the first component, wherein the drive system is designed such that the common cooling circuit is suitable for cooling the second component, wherein the first component has a first maximum temperature and a first threshold temperature, wherein the second component has a second maximum temperature, wherein the first maximum temperature is lower than the second maximum temperature, and wherein when the first threshold temperature is reached, the cooling performance provided for the second component is reduced.

Such a method achieves the objective because by reducing the cooling performance provided for the second component, more cooling efficacy is available for the first component, so that ultimately the first component can be operated for longer since its maximum temperature is reached less rapidly than when the cooling performance for the second component has not been reduced. In particular the inventors have recognized that in cases when the first component is an inverter and the second component is an electric motor, the electric motor typically often still has certain temperature reserves before its maximum permissible temperature is reached, i.e., in the present case the second maximum temperature, is reached when the inverter has already reached its maximum permissible temperature, i.e., in the present case the first maximum temperature.

In advantageous embodiments the drive system is an electric drivetrain wherein the first component comprises an inverter and wherein the second component comprises an electric motor. In typical embodiments the first component is an inverter and/or the second component is an electric motor. However, the first and second components do not necessarily have to be an inverter and an electric motor. Rather, in principle the method according to the invention can be used with any type of components in a drive system.

In typical embodiments the first threshold temperature is at least about 15%, preferably at least about 10% and advantageously at least about 5% lower than the first maximum temperature. The inventors have found that such separations between the first threshold temperature and the first maximum temperature are suitable for significantly prolonging the operation of a drive system. In this description and the claims that follow, the expression “about”, wherever it is used, is preferably to be understood to mean that a tolerance of ±20%, advantageously ±15% or ±10%, and best of all ±5% is intended.

In typical embodiments the first threshold temperature is measured at the inverter itself. In other embodiments the first threshold temperature is measured elsewhere in the common cooling circuit. Thus, in such cases the first threshold temperature corresponds to a particular temperature of a coolant in the common cooling circuit.

In advantageous embodiments, the common cooling circuit cools the first component directly and the second component indirectly, and for preference the common cooling circuit is a water-glycol cooling circuit. In principle, however, it is also conceivable for the common cooling circuit to cool both the first and the second component directly, or both of them indirectly. Moreover, in principle some medium other than a water-glycol mixture can be used in the common cooling circuit, for example just water.

In advantageous embodiments, the second component is cooled directly by a cooling circuit containing an air-oil mixture, wherein the air-oil-mixture cooling circuit is coupled with the common cooling circuit by way of a heat exchanger, preferably an oil-water heat exchanger. The inventors have found that such a design of the cooling system for the two components of the drive system is advantageous, because in that way the heat exchanger can be adjusted as necessary, so making it possible by virtue of this adjustment of the heat exchanger to influence the cooling performance available for the second component. In other words, this enables a coupling between the cooling circuit of the second component and the common cooling circuit to be reduced so that less heat is drawn away from the common cooling circuit, thereby improving the cooling of the first component. The cooling circuit of the second component, which cools the second component directly, does not necessarily have to be a cooling circuit containing an air-oil mixture. Rather, the direct cooling circuit of the second component can be some other cooling circuit, for example an air-cooling circuit or a water-glycol cooling circuit.

In advantageous embodiments the cooling performance for the second component is reduced by reducing the rotation speed of a pump of the heat exchanger. “The cooling performance for the second component” is here understood to mean the above-mentioned cooling performance made available to cool the second component. The inventors found that the use of a heat exchanger with a pump whose rotation speed can be varied is advantageous, because by reducing the pump rotation speed of such a heat exchanger, the volume of the coolant in the cooling circuit of the second component can be influenced directly. Thus, reducing the pump rotation speed of the heat exchanger results in a slower flow of the coolant that cools the second component directly, so that the common cooling circuit carries away the heat less rapidly. In that way, sufficient cooling for the first component is effective for longer. In practice this then means, for example, that if an inverter is the first component, then it can be operated for a longer time and accordingly the out-of-action time of the vehicle caused by overheating of the inverter is avoided, or at least reduced.

In typical embodiments, the cooling performance for the second component when an outside threshold temperature is reached, is reduced. Such a reduction of the cooling performance for the second component has the advantage, for example, that in winter, the second component can be warmed up more quickly. For example, in winter an electric motor can be warmed up more quickly. In typical embodiments, the outside threshold temperature is about 0° C., preferably about −5° C., and best of all about −10° C.

In advantageous embodiments the pump rotation speed is reduced by at least about 10% or at least about 25%, preferably by at least about 30% or at least about 50%, and advantageously by at least about 60% or at least about 75%. In advantageous embodiments, the pump rotation speed can be adjusted continuously. This has the advantage that a particularly favorable relationship between on the one hand sufficient cooling of the first component and on the other hand good efficiency of the heat exchanger pump can be achieved.

The objective is also achieved by a cooling system that comprises means for at least partially carrying out a method according to at least one of the above-mentioned embodiments.

Such a cooling system typically comprises at least one common cooling circuit, which is in particular a water-glycol cooling circuit, and preferably a further cooling circuit which is typically an air-oil-mixture cooling circuit. In typical embodiments, the common cooling circuit is suitable for cooling the first component directly. In typical embodiments, the further cooling circuit is suitable for cooling the second component directly. In typical embodiments, the common cooling circuit is coupled with the further cooling circuit by way of a heat exchanger. In advantageous embodiments, the heat exchanger comprises a pump which is designed to propel a coolant of the further cooling circuit, in particular an air-oil mixture, through the heat exchanger. In advantageous embodiments, the pump or the heat exchanger is designed such that a pump rotation speed can be varied, in particular continuously. In typical embodiments, the first component is an inverter. In typical embodiments, the second component is an electric motor.

In advantageous embodiments, the cooling system is suitable for at least partially carrying out and/or coordinating and/or controlling a method for cooling a drive system, according to at least one of the preceding embodiments. For that purpose, the cooling system advantageously comprises suitable components, for example, a component for recognizing a first threshold temperature and/or for recognizing a threshold outside temperature and/or a pump rotation speed reduction component and/or a pump rotation speed regulating component and/or a control component suitable for controlling the method.

To good advantage, in the cooling system at least some of the aforesaid components are implemented by means of computer program codes. In advantageous embodiments the cooling system, in particular at least some of the components, are at least partially part of a vehicle control system and/or a Cloud. In typical embodiments, the cooling system comprises a digital control unit and/or a display and/or data input means and/or data output means.

In an embodiment of the invention, a vehicle is suitable for carrying out a method according to at least one of the preceding embodiments. For that purpose, the vehicle typically comprises means for carrying out a method according to at least one of the preceding embodiments.

In an embodiment of the invention, a computer program contains commands which, when the computer program is run in a computer or a control unit, enable it to carry out one of the aforesaid methods. The computer program can also be referred to as a computer program product.

In an embodiment of the invention, a computer-readable medium contains computer program codes for carrying out one of the aforesaid methods. Here, the term “computer-readable medium” is understood to mean in particular, but not exclusively, hard disks and/or servers, and/or memory sticks, and/or a flash memory, and/or DVDs and/or Bluerays and/or CDs. In addition, the term “computer-readable medium” is also understood to mean a data stream produced, for example, when a computer program and/or a computer program product is downloaded from the internet.

### BRIEF DESCRIPTION OF THE DRAWINGS

Below, the invention is explained briefly with reference to drawings, which show:

FIG. 1: A schematic representation of a first embodiment of a method according to the invention,

FIG. 2: A schematic representation of a second embodiment of a method according to the invention, and

FIG. 3: A schematic representation of a cooling system according to the invention.

### DETAILED DESCRIPTION

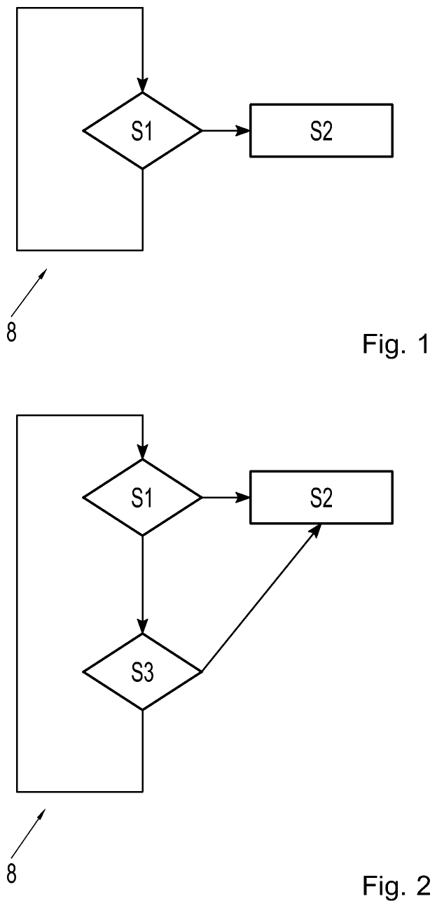

FIG. 1 shows a schematic representation of a first embodiment of a method 8 according to the invention. The method 8 is carried out in an endless loop symbolized by the rectangular arrow in FIG. 1. The method 8 is a method for cooling a drive system, the drive system itself not being shown in FIG. 1. The method 8 comprises a first threshold temperature checking step S1, which is carried out periodically in the endless loop. In this first threshold temperature checking step S1 it is ascertained whether a first threshold temperature of a first component of the drive system (not shown in FIG. 1) has been reached. If not, the endless loop is continued normally. If so, then a cooling performance reduction step S2 is initiated, in which a cooling performance applied to cool a second component of the drive system (not shown in FIG. 1) is reduced. Although the method for cooling a drive system 8 is shown in FIG. 1 as an endless loop with periodic carrying out of the first threshold temperature checking step S1, it is also possible that an endless loop is not carried out directly, but rather, the cooling performance reduction step S2 is activated as necessary if in the process 8 it is recognized that the first threshold temperature of the first component has been reached. In other words, it is not unconditionally necessary to query the first threshold temperature periodically, but rather, it is also possible for example for a temperature sensor to report that a first threshold temperature has been reached, whereby the cooling performance reduction step S2 is then started. In FIG. 1 it is not explicitly shown that at some later time, when a temperature of the first component is no longer at the first threshold temperature, the cooling performance reduction step S2 is terminated again, whereby the cooling performance applied to cool the second component is no longer reduced. However, this termination of the cooling performance reduction step S2 at such a later time is included in an advantageous embodiment of the method according to the invention.

FIG. 2 shows a schematic representation of a second embodiment of a method 8 according to the invention for cooling a drive system (again, not shown). The method 8 in FIG. 2 is very similar to the method already shown in FIG. 1, and all that has been said in relation to FIG. 1 also applies in principle to the embodiment of the method 8 shown in FIG. 2. In addition, however, the method 8 shown in FIG. 2 comprises another threshold outside temperature checking step S3. In this threshold outside temperature checking step S3 it is periodically checked whether an outside temperature, for example a temperature outside a vehicle in which the method 8 is taking place, has reached a certain threshold value. Such a threshold value can be, for example, 0° C., −5° C. or even −10° C. If it is recognized in the threshold outside temperature checking step S3 that such a threshold value has been reached, then the cooling performance reduction step S2 is likewise activated. In this way, if outside temperatures are low, then an operating temperature of the second component can be reached more rapidly. In such a case, the cooling performance reduction step S2 is typically terminated as soon as the second component has reached its operating temperature.

In a particular example embodiment, the first component mentioned in relation to FIGS. 1 and 2 is an inverter and the second component mentioned in relation to those figures is an electric motor.

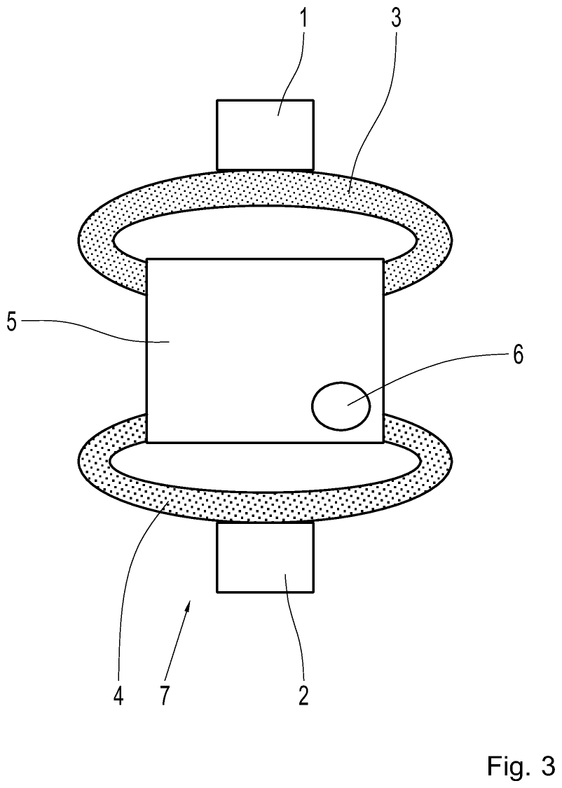

FIG. 3 shows a schematic representation of a cooling system 7 according to the invention. The cooling system 7 comprises a common cooling circuit 3, an air-oil-mixture cooling circuit 4, a heat exchanger 5 and a pump 6. In FIG. 3 it is shown how the cooling system 7 cools an inverter 1 and an electric motor 2. For that, the common cooling circuit 3 cools the inverter 1 directly and the air-oil-mixture cooling circuit 4 cools the electric motor 2 directly. The air-oil-mixture cooling circuit 4 can be some other cooling circuit, and for that reason the air-oil-mixture cooling circuit can also be referred to as the “further” cooling circuit and is also called the further cooling circuit in what follows. The common cooling circuit 3 and the further cooling circuit 4 are coupled with one another by way of the heat exchanger 5. Thus, it can be said that the common cooling circuit 3 cools not only the inverter 1, but indirectly also the electric motor 2, namely, by way of the heat exchanger 5 and the further cooling circuit 4. The pump 6 of the heat exchanger 5 controls the through-flow of the cooling medium in the air-oil-mixture cooling circuit 4. This cooling medium (also called the coolant) is typically an air-oil mixture. Normally the pump 6 runs at full load, in particular at its maximum rotation speed. But when it is recognized that the inverter 1 is getting too hot, in particular that it has reached its first threshold temperature, then in the method according to the invention the pump is downward regulated, in particular by reducing its rotation speed. Consequently, the cooling medium flows less rapidly through the further cooling circuit 4, so that heat is transferred less rapidly from the common cooling circuit 3 into the further cooling circuit 4. In other words, a cooling performance applied to cool the electric motor 2 is reduced by the reduction of the rotation speed of the pump 6. This means that for the inverter 1 more of the cooling performance is available, so that a maximum permissible temperature (also called the maximum temperature) of the inverter 1 is reached less rapidly. The result is that the inverter 1, which in an electric drivetrain is typically the critical component in relation to the operating temperature, can be operated for longer, so that switching off the electric drivetrain, and therefore also the vehicle in which the electric drivetrain is installed, can be avoided or at least delayed.

The invention is not limited to the example embodiments described. Its protective scope is defined by the claims.

In principle all the methods described in the description section or in the claims can be carried out by devices that comprise means for carrying out the respective process steps of this method.

### INDEXES

1 Inverter
2 Electric motor
3 Common cooling circuit
4 Air-oil-mixture cooling circuit
5 Heat exchanger
6 Pump
7 Cooling system
8 Method for cooling a drive system
S1 First threshold temperature checking step
S2 Cooling performance reduction step
S3 Threshold value outside temperature checking step

1-11. (canceled)

12. A method (8) for cooling a drive system, the method comprising:
providing a drive system having a first component (1) with a first threshold temperature and a first maximum temperature, wherein the first threshold temperature is lower than the first maximum temperature;
providing a second component (2) having a second maximum temperature;
providing a common cooling circuit (3) suitable for cooling the first component (1), wherein the first component (1) has a first maximum temperature that is lower than the second maximum temperature;
determining that the first threshold temperature has been reached; and
reducing performance of the cooling applied to cool the second component (2).

13. The method (8) according to claim 12, wherein the drive system is an electric drive system, wherein the first component (1) comprises an inverter (1), and wherein the second component (2) comprises an electric motor (2).

14. The method (8) according to claim 12, wherein the first threshold temperature is lower than the first maximum temperature by at least 5%.

15. The method (8) according to claim 14, wherein the first threshold temperature is lower than the first maximum temperature by at least 10%.

16. The method according to claim 14, wherein the first threshold temperature is lower than the first maximum temperature by at least 15%.

17. The method (8) according to claim 12, wherein the common cooling circuit (3) is configured to cool the first component (1) directly and to cool the second component (2) indirectly.

18. The method (8) according to claim 17, wherein the common cooling circuit (3) comprises a water-glycol cooling circuit.

19. The method (8) according to claim 14, wherein the second component (2) is cooled directly by an air-oil-mixture cooling circuit (4), and the air-oil-mixture cooling circuit (4) is coupled with the common cooling circuit (3) by way of a heat exchanger (5).

20. The method according to claim 19, wherein the heat exchanger (5) is configured as an oil-water heat exchanger.

21. The method (8) according to claim 19, wherein reducing the cooling performance of the second component (2) is performed by reducing a pump rotation speed of the heat exchanger (5).

22. The method (8) according to claim 12, comprising:
determining that an outside temperature threshold value has been reached; and
reducing the cooling performance for the second component (2).

23. A cooling system, comprising means for at least partially carrying out the method (8) according to claim 12.

24. A vehicle configured to carrying out the method (8) according to claim 12.

25. A computer-readable medium containing executable code which, when executed by a computer or a control unit, performs the method (8) according to claim 12.
